(19) United States
(12) Patent Application Publication
(10) Pub. No.: US 2008/0043487 A1
(43) Pub. Date: Feb. 21, 2008

(54) LIGHT BAR STRUCTURE HAVING LIGHT CONDUITS AND SCANNED LIGHT DISPLAY SYSTEM EMPLOYING SAME

(76) Inventor: Randall B. Sprague, Carnation, WA (US)

Correspondence Address: Michael G. Pate, Esq.;DORSEY & WHITNEY LLP, Suite 3400, 1420 Fifth Avenue, Seattle, WA, 98101, US

(21) Appl. No.: 11/836,714

(22) Filed: Aug. 9, 2007

Related U.S. Application Data
(60) Provisional application No. 60/839,263, filed on Aug. 21, 2006.

(51) Int. Cl. F21V 8/00; G09G 5/00; H01L 33/00

(52) U.S. Cl. 362/581; 345/8; 438/31; 257/E33.071

(57) ABSTRACT

Apparatuses and methods for light bar structures and scanned light display systems. A light bar structure includes an elongated support arm having a plurality of light conduits. Each of the light conduits includes at least one input portion and a distal output end. A plurality of light emitters may be mounted on the support arm, each of the light emitters being positioned over an input portion of a corresponding one of the light conduits and operable to provide light thereto so that the light is optically coupled to the corresponding one of the light conduits and output from the output end thereof as diverging light. A scanned light display system includes a curved mirror positioned to receive the diverging light and configured to substantially collimate the received light. An actuator is operable to relatively move the light bar structure and the curved mirror to scan the collimated light to form an image.

### CROSS-REFERENCE TO RELATED APPLICATION

This application claims the benefit of U.S. Provisional Application No. 60/839,263, filed Aug. 21, 2006.

The entire disclosure of the prior application is considered to be part of the disclosure of the instant application and is hereby incorporated by reference therein.

### TECHNICAL FIELD

This invention relates to an improved light bar structure for use in a scanned light display. More particularly, this invention relates to an improved light bar structure having a plurality of light conduits and scanned light displays that employ them.

### BACKGROUND

A variety of techniques are available for providing visual displays of graphical or video images to a user. In many applications cathode ray tube type displays (CRTs), such as televisions and computer monitors, produce images for viewing. Such devices suffer from several limitations. For example, typical CRTs are bulky and consume substantial amounts of power, making them undesirable for portable or head-mounted applications.

Matrix addressable displays, such as liquid crystal displays and field emission displays, may be less bulky and consume less power. However, typical matrix addressable displays utilize screens that are several inches across. Such screens have limited use in head mounted applications or in applications where the display is intended to occupy only a small portion of a user's field-of-view. Such displays have been reduced in size at the cost of increasingly difficult processing and limited resolution or brightness. Also, improving resolution of such displays typically requires a significant increase in complexity.

Another form of display is a scanned light display. Scanned light displays are sometimes used for partial or augmented view applications in which a portion of the display is positioned in the user's field-of-view to create an image that occupies a region of the user's field-of-view. The user can thus see both a displayed virtual image and a background image. If the background light is occluded, the viewer perceives only the virtual image. Applications for see-through and occluded scanned light displays include head-mounted displays and camera electronic viewfinders, for example.

One example of a scanned light display is disclosed in U.S. patent application Ser. No. 11/078,970, entitled SCANNED LIGHT DISPLAY SYSTEM USING LARGE NUMERICAL APERTURE LIGHT SOURCE, METHOD OF USING SAME, AND METHOD MAKING SCANNING MIRROR ASSEMBLIES (“the '970 Application”), filed on Mar. 9, 2005 and commonly assigned herewith, the disclosure of which is incorporated herein by reference. FIG. 1 shows one embodiment of a scanned light display 100 disclosed in the '970 Application. The display 100 includes a substantially stationary curved mirror 102, such as a spherical mirror, aligned directly with a pupil 114 of a viewer's eye 112. An array 104 of light emitters 105 extending generally in the x-axis direction is positioned in front of the viewer's pupil 114 on or proximate the focal surface of the curved mirror 102. Light 106 emitted by the light emitters 105 may radiate outwardly over a substantially hemispherical solid angle to strike the curved mirror 102. Light 106 emitted from each of the light emitters 105 hitting the curved mirror 102 is substantially collimated by the curved mirror 102 into respective beams 108 and directed back to the pupil 114 where it is focused by the lens 116 of the viewer's eye 112 onto the viewer's retina 118. The display 100 further includes a filter 110 positioned in front of the viewer's eye 112 and configured to filter extraneous light reflected from the curved mirror 102. As shown in FIG. 2, the array 104 is curved to correspond to the curvature of the focal surface of the curved mirror 102 and includes a large number of the light emitters 105, such as light emitting diodes (LEDs), spaced apart and mounted on the front surface 120 of a light bar support arm 122.

In operation, the light 106 emitted by each of the light emitters 105 is substantially collimated into beams 108 and scanned by vertically moving the array 104, shown at three positions 104, 104′, and 104″, while the curved mirror 102 is maintained substantially stationary in order to form the displayed image. Vertically moving the array 104 alters the location and angle at which the beams 108 are directed by the curved mirror 102 onto the pupil 114 of the viewer. If the array 104 is fully populated with the light emitters 105 in the horizontal direction (i.e, the light emitters not being spaced apart), the array 104 only needs to be scanned in the vertical z-axis direction.

While the display 100 is an effective scanned light display, there is a continual need to improve the design of the overall display and individual components thereof.

### SUMMARY

Light bar structures, methods of making the light bar structures, and scanned light display systems employing the light bar structures are disclosed. Methods of operation of the light bar structures and scanned light display systems are also disclosed.

One aspect is directed to a light bar structure for use in a scanned light display. The light bar structure includes an elongated support arm having a plurality of light conduits formed therein. Each of the light conduits includes at least one input portion and a distal output end. A plurality of light emitters may be mounted on the support arm and each of the light emitters is operable to emit light. Each of the light emitters is positioned adjacent the at least one input portion of a corresponding one of the light conduits so that the light emitted from each of the light emitters is optically coupled to the corresponding one of the light conduits and output from the output end thereof as diverging light.

Another aspect is directed to a scanned light display system. The display system includes at least one light bar structure having an elongated support arm with a plurality of light conduits formed therein. Each of the light conduits includes at least one input portion and a distal output end. A plurality of light emitters may be mounted on the support arm and each of the light emitters is operable to emit light. Each of the light emitters is positioned adjacent the at least one input portion of a corresponding one of the light conduits so that the light emitted from each of the light emitters is optically coupled to the corresponding one of the light conduits and output from the output end thereof as diverging light. The display further includes a curved mirror positioned to receive at least a portion of the diverging light from the plurality of light conduits of the at least one light bar structure and configured to substantially collimate the received diverging light. An actuator is coupled to at least one of the light bar structure and the curved mirror. The actuator is operable to move the light bar structure and the curved mirror relative to each other to scan the substantially collimated light to form an image.

Yet another aspect is directed to a method of making the light bar structure having a support arm with a plurality of light conduits formed therein. The method includes forming a plurality of light transmissive trenches in a substrate, each of the trenches having at least one input portion and a distal output end. Each of the trenches is covered with at least one layer of material to define a plurality of light conduits. An aperture may be formed in the at least one layer of material adjacent each of the input portions. A plurality of light emitters are positioned over the apertures so that each of the light emitters is adjacent one of the apertures. The support arm is released from the substrate, for example, by a deep etch process such as deep reactive ion etching (DRIE).

### BRIEF DESCRIPTION OF THE DRAWINGS

FIG. 1 is a schematic cross-sectional view of a scanned light display in which the array of light emitters can be moved while the curved mirror remains substantially stationary according to the prior art.

FIG. 2 is a schematic isometric view of the array of light emitters shown in FIG. 1.

FIG. 3 is a schematic top view of a light bar structure according to one embodiment.

FIG. 4 is a schematic partial front view of the curved portion of the light bar structure of FIG. 3 showing the light conduits thereof according to one embodiment.

FIG. 5 is a schematic partial top view of the light bar structure showing the configuration of the plurality of light conduits for the light bar structure according to one embodiment.

FIG. 6 is a schematic partial top view of the light bar structure showing the configuration of the plurality of light conduits for the light bar structure according to another embodiment.

FIG. 7 is a schematic longitudinal cross-sectional view taken along the length of one of the light conduits illustrating the configuration of the rear surface of the light conduit according to one embodiment.

FIG. 8A is a schematic longitudinal cross-sectional view taken along the length of one of the light conduits illustrating the configuration of the rear surface of the light conduit according to another embodiment.

FIG. 8B is a schematic longitudinal cross-sectional view taken along the length of one of the light conduits illustrating the configuration of the rear surface of the light conduit according to yet another embodiment.

FIG. 9 is a schematic partial front view of the curved portion of the light bar structure of FIG. 3 showing the light conduits thereof according to another embodiment.

FIGS. 10A-10J, and 10L are schematic partial cross-sectional views of in-process structures at different process steps during fabrication of the light conduits of the light bar structure of FIG. 3 according to one embodiment of a method.

FIG. 10K is a schematic top view of a substrate with a plurality of support arms formed therein having the in-process light conduit structure shown in FIG. 10J.

FIG. 11 is a schematic cross-sectional view of a scanned light display that employs the light bar structure of FIG. 3 according to one embodiment.

FIG. 12 is a simplified block diagram of a scanned light display system that may be used with the display of FIG. 11 according to one embodiment.

FIG. 13 is a block diagram of a scanned light display system used in conjunction with, or as a subsystem of, a still or video camera or other stored image viewing system according to one embodiment.

FIG. 14 is a block diagram of a media viewer capable of rendering still and/or video images to a user from a streaming and/or wireless media source according to one embodiment.

### DETAILED DESCRIPTION OF THE EMBODIMENTS

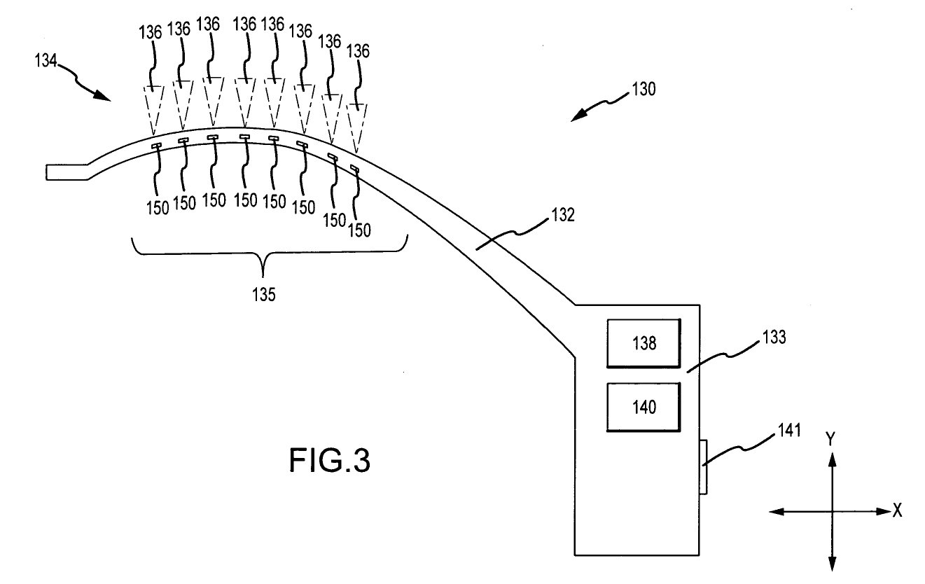

Embodiments disclosed herein are directed to improved light bar structures, methods of manufacture of the improved light bar structures, and scanned light displays that employ the improved light bar structures. Many specific details of certain embodiments are set forth in the following description and in FIGS. 3 through 14 in order to provide a thorough understanding of such embodiments. One skilled in the art, however, will understand that there may be additional embodiments, or that the disclosed embodiments may be practiced without several of the details described in the following description.

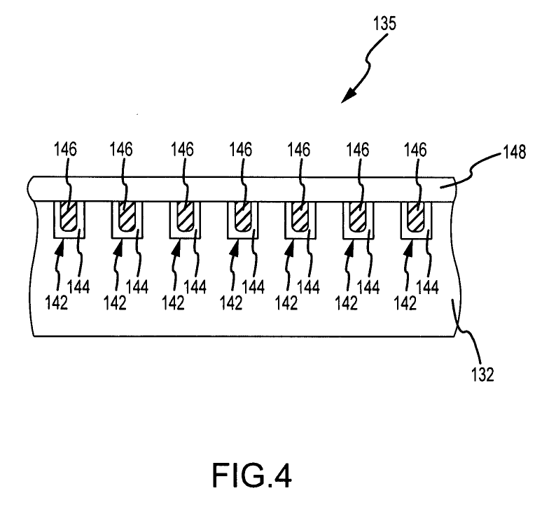

FIG. 3 shows a schematic top view of a light bar structure 130 for use in a scanned light display system according to one embodiment. The light bar structure 130 includes a relatively thin support arm 132 extending generally in the x-axis direction and having a curved portion 135 that has a plurality of light emitters 150 mounted thereon. The thickness of the support arm 132 may be, for example, approximately 525 μm and the light emitters 150 may be approximately 50 μm thick to form a structure with an overall thickness of approximately 575 μm. Each of the light emitters 150 provide light to corresponding light conduits formed within the curved portion 135 (see FIGS. 4-9, not shown in FIG. 3) and direct such light so that it is output from the output side 134 of the curved portion 135 as divergent light 136. Various embodiments for the configuration of the light conduits, fabrication methods, and applications in a scanned light display system will be discussed below in more detail with respect to FIGS. 4 through 14. A hinge attachment portion 133 having a hinge mechanism 141 attached to it extends from the support arm 132. The hinge attachment portion 133 may carry one or more actuators 138 and electronic circuitry 140 associated with the light emitters 150 and/or the one or more actuators 138, and may be integrally formed with the support arm 132. The actuator 138 may include a plurality of actuators that are operable to rotate the support arm 132 about the x-axis and optionally to laterally move the support arm 132 along the x-axis direction.

FIG. 4 shows a partial front schematic view of the curved portion 135 of the light bar structure 130. The curved portion 135 includes a plurality of light conduits 142 formed therein defined by the volume between a first reflecting portion 144 and a second reflecting portion 148 formed thereover. The light conduits 142 extend transversely through the curved portion 135. The first and second reflecting portions 144 and 148 may be formed of silver, gold, aluminum, alloys thereof, or another suitable material. Depending upon the application, it may be advantageous to eliminate separate reflective portions 144 and/or 148 from the light conduit 142 and rely instead on reflective properties of the bulk substrate 132, and orientation or proximity of the light emitters. In some embodiments, the light conduit 142 defined by the volume between the first reflecting portion 144 and the second reflecting portion 148 may be filled with a plug of dielectric material 146 formed from a dielectric material such as, for example, silicon dioxide. In other embodiments, the volume defined by the volume between the first reflecting portion 144 and the second reflecting portion 148 may be filled with air, vacuum, or other gaseous or liquid medium. In such cases, it may be advantageous to make the second reflecting portion from a self-supporting material or a material plated on an upper substrate (not shown). Each of the light conduits 142 may be laterally spaced apart from each other a distance smaller than the human eye is capable of resolving or a distance that is small relative to the lateral extent of the light conduits. The light conduits 142 may be laterally spaced apart a distance smaller than the resolution of the image to be ultimately formed from pixels formed from the light 136 provided by the light conduits 142. In one embodiment, each of the light conduits 142 corresponds to a pixel in a horizontal image line to be formed. In other embodiments, the number of the light conduits 142 is less than the number of pixels in a horizontal image line.

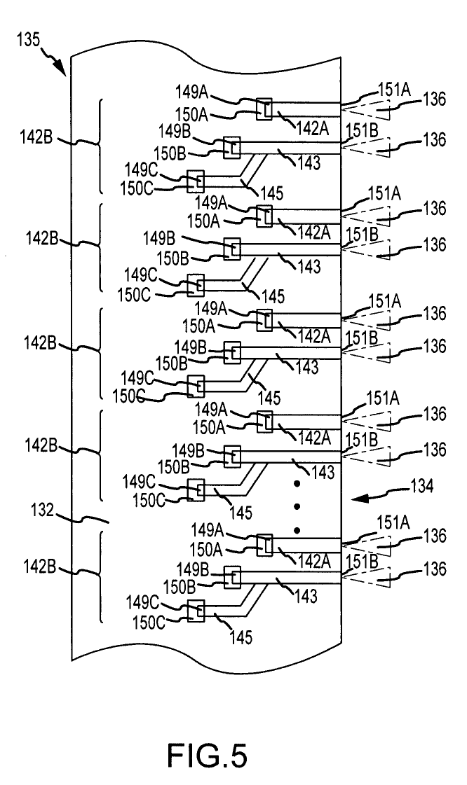

FIG. 5 is a schematic top view of the curved portion 135 that illustrates one embodiment for the configuration of the plurality of light conduits 142. The plurality of light conduits 142 may be arranged in sets of light conduits. Each set may include two light conduits 142a-142b. Each of the light conduits 142a has a corresponding light emitter 150a positioned over a corresponding input end 149a. Each of the light conduits 142b has a first section 143 with a corresponding input end 149b having the light emitter 150b positioned thereover and a second section 145 with a corresponding input end 149c having the light emitter 150c positioned thereover. The light emitters 150a-150c are operable to emit light into the respective input ends of the light conduits 142a, 142b and may be light emitting diodes (LEDs), organic LEDs (OLEDs), or another suitable light source. In some embodiments, the light emitters 150a-150c are operable to emit diverging light.

With continuing reference to FIG. 5, in one embodiment, the light emitters 150a are green light emitters and the light emitters 150b and 150c are red and blue light emitters, respectively. For example, blue light emitted from the light emitters 150c is optically coupled to corresponding second sections 145 of light conduits 142b through an input end 149c and travels along the length thereof and provides blue light to the first section 143 of the light conduit 142b, which is intersected by the second section 145. Red light emitted from the light emitters 150b is optically coupled to corresponding first section 143 of light conduits 142b and travels along the length thereof. Light output from an output end 151b of the light conduits 142b will be a combination of both red and blue light. Green light emitted from the light emitters 150a is optically coupled to corresponding light conduits 142a through the input end 149a and travels along the length thereof and is output from an output end 151a as green light. In this embodiment, the green light has its own light conduit 142a to improve the optical coupling of the green light with its light conduit 142c due to the low intensity of currently available green light sources and the characteristics of the human eye. Optically coupling the green light to a single light conduit 142a may aid in forming a white balanced image, which is formed of approximately seventy percent green light. However, if the intensity of the green light is not a significant concern, according to one embodiment, the light conduit 142a may also intersect the light conduit 142b so that a combination of green, red, and blue light is selected to provide the desired color may be output from the output end 151 of the light conduits 142b. Alternatively, each color of light emitter may be coupled into individual light conduits.

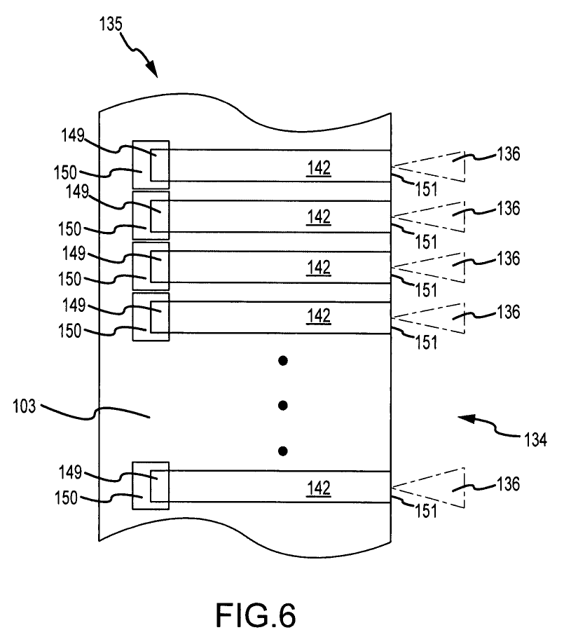

FIG. 6 shows another embodiment for the arrangement of the light conduits 142 suitable for a monochrome light source or light emitters coupled into individual light conduits. The light conduits 142 may have a light emitter 150 positioned over an input end 149 distal from the output end 151 of the output side 134. In this embodiment, each of the light emitters 150 may provide light of the same wavelength or range of wavelengths. In another embodiment suitable for a full color light source, each of the light emitters 150 may be an RGB (red/green/blue) triad or RGBG (red/green/blue/green) quadrad.

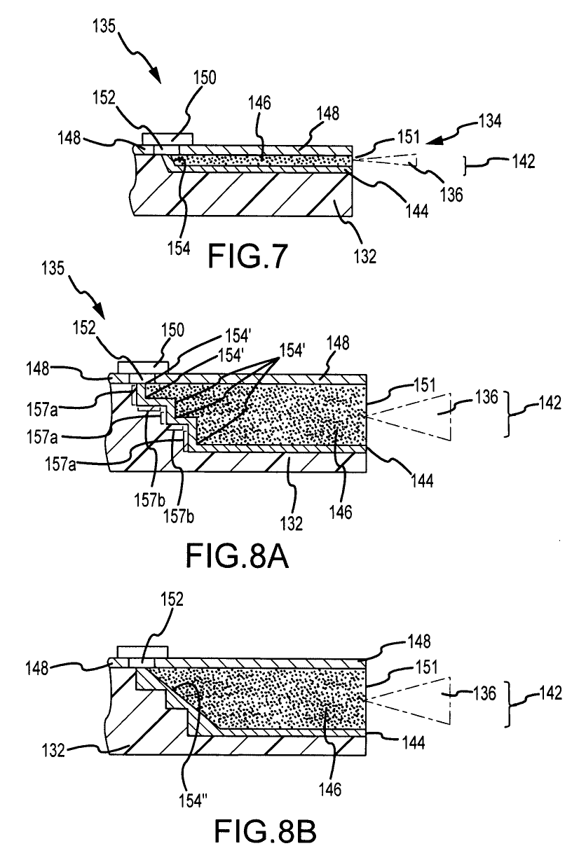

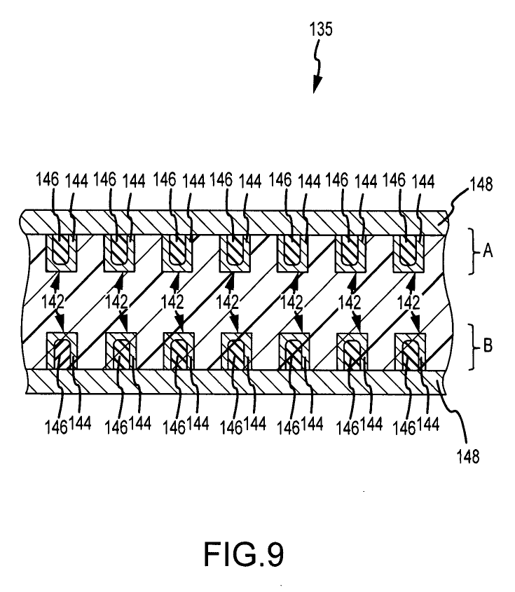

FIGS. 7 and 8 are schematic longitudinal cross-sectional views taken along the length of one of the light conduits 142. FIGS. 7 and 8 more clearly show how light emitted from one of the light emitters 150 is optically coupled to a corresponding one of the light conduits 142 and directed along the length of the light conduits 142 to be output from the output end 151. An aperture 152 is formed in the second reflecting portion 148 and positioned over a rear surface 154 of the light conduit 142 so that light emitted from the light emitter 150 is transmitted through the plug of dielectric material 146, if present, and reflected from the rear surface 154. The reflected light is directed along the length of the light conduit 142 through the plug 146 and confined within the plug 146 until it is output from the output end 151 of the curved portion 134 as divergent light 136. As shown in the embodiment of FIG. 7, the rear surface 154 of the first reflecting portion 144 may be oriented at an angle, such as an approximately forty-five degree angle relative to the bottom surface of the light conduit 142, so that light emitted from the light emitters 150 is reflected from the rear surface 154 and directed along the length of the light conduit 142. In the embodiment shown in FIG. 8A, the light conduit 142 has a rear surface 154′ having a “stepped” configuration with one or more rear walls 157a and ledges 157b that function to reflect the light emitted from the light emitters 150 and direct it along the length of the light conduit 142 in a similar manner to the rear surface 154. In yet another embodiment, the light conduit 142 has a rear surface 154″ formed by defining steps in the support arm 132 and reflowing the first reflecting portion 144, which is deposited on the steps, at a sufficient temperature so that it has a substantially constant slope similar to the embodiment shown in FIG. 7.

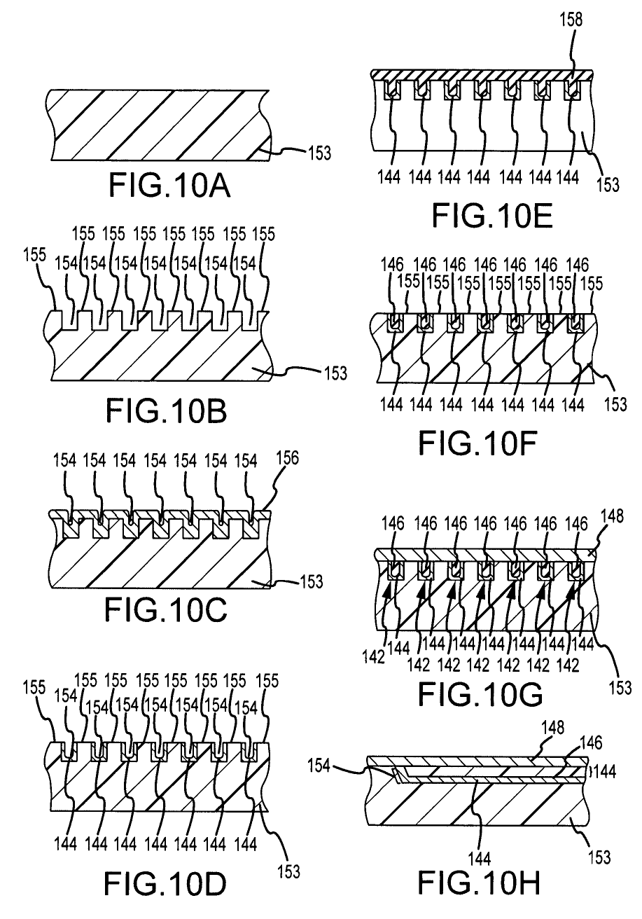

FIG. 9 shows a schematic partial front view of the curved portion 135 of the light bar structure 130 in which the light conduits 142 are arranged in an upper row A and a lower row B. Such an embodiment facilitates forming a greater number of the light conduits 142 in the curved portion 135. In some embodiments, the lower row B of the light conduits 142 may have, for example, corresponding green light emitters for providing green light and the upper row A of the light conduits 142 may have, for example, corresponding red and blue light emitters for providing a combination of red and blue light. In another embodiment, light conduits 142 in the lower row B may be offset from the light conduits in the upper row A by one-half the pitch. This approach may be used, for example, to effectively double the horizontal resolution of the light bar.

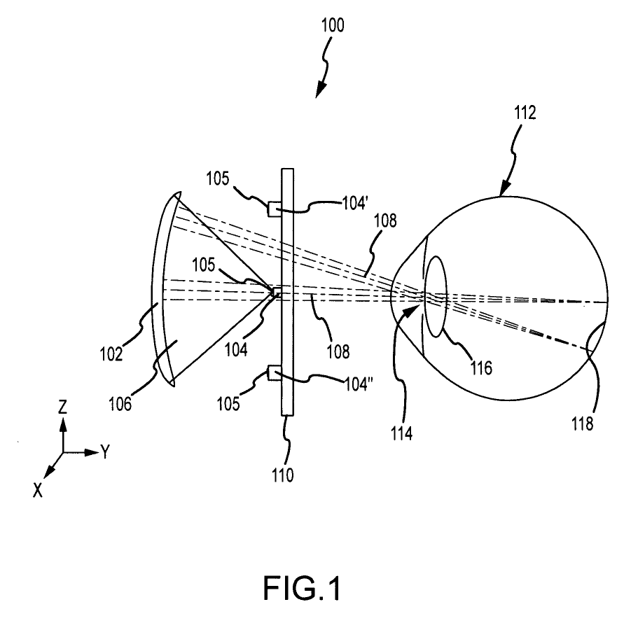

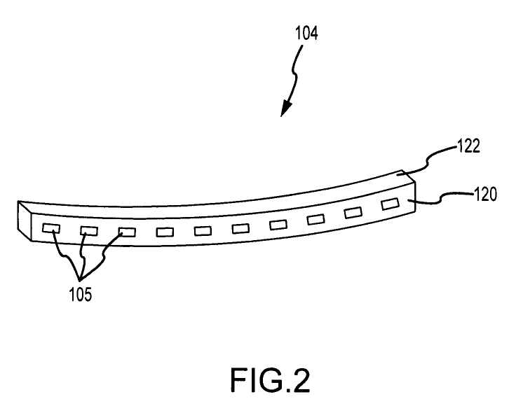

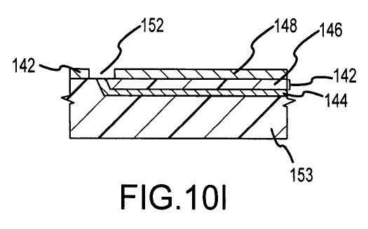

FIGS. 10A-10L illustrate various embodiments of a method for forming the light conduits 142. In FIGS. 10A and 10B, a semiconductor substrate 153, such as a full or partial silicon wafer is provided and trenches 154 are formed therein using conventional photolithography and etching techniques. Although not shown in FIG. 10B, the configuration of the rear of the trench 154 as shown in FIGS. 7-8B, may also be formed before, during, or after this step. As shown in FIG. 10C, at least one layer 156, formed of a metal or alloy, is deposited within the trenches 154 and over the upper surfaces 155 between adjacent trenches 154. The layer 156 may be deposited using techniques such as, for example, chemical vapor deposition (CVD), physical vapor deposition (PVD), or atomic layer deposition (ALD). Next, in FIG. 10D, the portion of the layer 156 on the upper surfaces 155 between adjacent trenches may be removed by appropriate masking and etching or a suitable planarization process, such as chemical-mechanical polishing (CMP), to define the first reflecting portion 144. In FIG. 10E, at least one layer of dielectric material 158 is deposited over the first reflecting portion 144 to fill the trenches 154 and cover the upper surfaces 155 between adjacent trenches 154. The layer of dielectric material 158 may be deposited using techniques such as, for example, CVD, PVD, or ALD. Again, as shown in FIG. 1 OF, the layer of dielectric material 158 covering the upper surfaces 155 may be removed by etching or planarization to form the plugs 146. In one embodiment, the layer 156 is not planarized or etched, and the layer of dielectric material 158 is deposited to also cover the portion of the layer 156 formed over the upper surface 155. Then, both the layer 156 and 158 that are formed over the upper surface 155 may be removed by etching or planarizing in the same process step.

Next, as shown in FIGS. 10G and 10H, the second reflecting portion 148 is deposited and formed over the upper surfaces 155 and the upper surfaces of the plugs 146. The second reflecting portion 148 may be deposited using techniques such as, for example, CVD, PVD, or ALD. The volume between the first reflecting portion 144 and the second reflecting portion 148 defines the light conduits 142. As shown in FIG. 101, after depositing the second reflecting portion 148, the apertures 152 may be formed in the second reflecting portion 148 using conventional photolithography and etching techniques. As shown in FIG. 10J, a backside metallization layer 174 may be formed on the backside of the substrate 153 by CVD, PVD, or ALD. After the backside metallization layer 174 is formed, as shown in FIG. 10K, the support arms 132 may be formed in the substrate 153 and interconnected together through bridges 176. The support arms 132 and the bridges 176 may be formed by employing an etching process such as, for example, deep reactive ion etch (DRIE) from the top of the substrate 153 to form deep vertical trenches to almost separate the support arms 132. In another embodiment, the bridges 176 may be omitted and the support arms 132 may be etched from the substrate 153 and are supported only by the backside metallization layer 174. While FIG. 10K shows only the support arms 132 being formed from a large substrate 153, such as full silicon wafer, the hinge attachment portion 133 (see FIG. 3) may also integrally be formed with the support arm 132. The layout selected to form the support arm 132 with its hinge attachment portion 133 may be different from the layout shown in FIG. 10K in order to maximize the yield from the substrate 153. This type of etching process is described in more detail in U.S. patent application Ser. No. 10/986,635, entitled METHOD AND APPARATUS FOR MAKING A MEMS SCANNER, filed on Nov. 12, 2004 and commonly assigned herewith, the disclosure of which is incorporated herein by reference.

As shown in FIG. 10L, the light emitters 150 may be placed in their desired location proximate to corresponding rear surfaces 154 of corresponding light conduits 142 by providing a structure having the light emitters 150 located in a corresponding pattern, which facilitates accurately placing the light emitters 150 over the corresponding apertures 152. This advantageously allows the light emitters 150 to be mounted on a relatively planar surface eliminating problems associated with mounting the light emitters 150 on a curved surface. Also, there may be some misalignment between the light emitters 150 and corresponding apertures 152 without degrading optical coupling of the light emitters 150 to the light conduits 142 as long as the light emitters 150 are able to provide a sufficient amount of light to a corresponding one of the light conduits 142. In one embodiment, the light emitters are OLEDs and the OLEDs may be pad printed within the apertures 152 onto the upper surface of the dielectric plug 146.

The support arms 132 with the light emitters 150 mounted thereon may be singulated from the substrate 153 by tearing the backside metallization layer 174, breaking the bridges 176, or both, if present. In other embodiments in which the bridges 176 are omitted, the backside metallization layer 174 may be etched away to singulate the support arms 132. In yet another embodiment, the backside metallization layer may be omitted and only the bridges 176 are used to support the support arms 132. In this embodiment, the bridges 176 are broken to singulate the support arms 132.

In another embodiment, instead of forming the second reflecting portion 148 by depositing material onto the substrate 153, a thin metal foil or plate having the light emitters 150 arranged in a pattern corresponding to the desired position proximate to the rear surface 154 of the light conduits 142 may be bonded to or otherwise secured over the substrate 153. This embodiment is suitable for applications where the dielectric material 146 of the light conduits 142 is formed from vacuum, gas, or liquid entities.

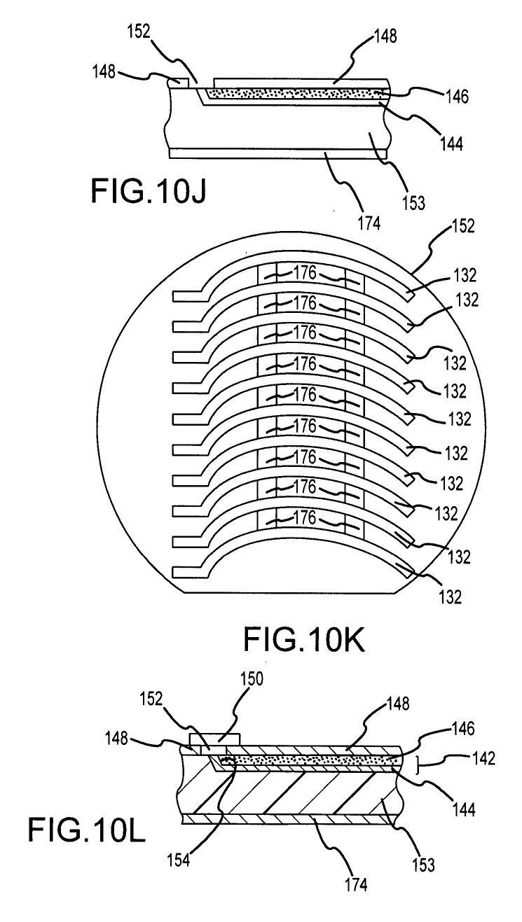

FIG. 11 shows one embodiment of a scanned light display 160 that employs one or more of the aforementioned light bar structures 130. The display 160 includes a curved mirror 162, such as a spherical mirror, aligned directly with a pupil 164 of a viewer's eye 163. Although the various embodiments will be described as using a curved mirror 162, according to another embodiment, a diffractive optical element may be substituted for the curved mirror 162 described herein. It will be understood that, as modifications to the mirror shape such as adaptation to a Fresnel type mirror remain within the scope, so too does the adaptation to a diffractive element of arbitrary shape. In the interest of brevity and clarity, the term “curved mirror” will be understood to include such alternative mirror types. The light bar structure 130 that extends generally in the x-axis direction is positioned in front of the viewer's pupil 164. Since the light bar structure 130 is relatively thin, any shadowing affect from it may be reduced. One or more of the actuators 138 are coupled to the light bar structure 130 and operable to move the light bar structure 130 in a selected direction. For example, a vertical actuator 138 may be a magnetic or piezoelectric actuator operable to resonantly scan the light bar structure 130 vertically in the z-axis direction and a horizontal actuator 138 may be a piezoelectric actuator operable to scan the light bar structure 130 horizontally in the x-axis direction in a non-resonant manner. The display 160 may also include one or more actuators 178 that are coupled to the curved mirror 162 operable to move the curved mirror 162. The actuator 178 may be the type disclosed in the aforementioned '970 Application.

In one embodiment, the curved portion 135 of the light bar structure 130 is curved to correspond to the curvature of the curved mirror 162, and the output ends 151 (see FIGS. 5-8B, not shown in FIG. 11) of the light conduits 142 are positioned on or proximate the focal surface of the curved mirror 162 so that the light 136 emanating therefrom is substantially collimated by the curved mirror 162. As previously discussed, the light 136 emanating from respective light conduits 142 of the light bar structure 130 is divergent light and radiates outwardly over a substantially hemispherical solid angle to strike the curved mirror 162. The light 136 missing the curved mirror 162 may be absorbed by a display housing (not shown). The light 136 from the light conduits 142 hitting the curved mirror 162 is substantially collimated by the curved mirror 162 into respective beams 172 and directed back to the pupil 164 where it is focused by the lens 166 of the viewer's eye 163 onto the viewer's retina 168. In some embodiments, the display 160 further includes a filter 174 positioned in front of the viewer's eye 163 and configured to filter extraneous light reflected from the curved mirror 162.

In operation, the light 136 emanating from the output ends 151 of the light conduits 142 is substantially collimated by the curved mirror 162 into respective beams 172 and scanned by vertically moving the light bar structure 130, while the curved mirror 102 is maintained substantially stationary in order to form the displayed image. Each image frame is formed by the modulation of the intensity of the light emitters 150, which may be modulated either simultaneously or sequentially, in conjunction with scanning of the beams 172 reflected from the curved mirror 162. Vertically moving the light bar structure 130 alters the location and angle at which the beam 172 is directed by the curved mirror 162 onto the pupil 164 of the viewer's eye 163. In some embodiments, the light bar structure 130 may be moved vertically by rotating it about the axis parallel to the x-axis so that the distance between output ends 151 of the light conduits 142 and the curved mirror 162 remains constant as the light bar structure 130 is moved. In one embodiment, the light bar structure 130 is fully populated with the light conduits 142 in the horizontal x-axis direction and the beams 172 only need to be scanned in the vertical z-axis direction at a frame rate of, for example, 60 Hz, and each of the light emitters 150 is modulated at a frequency of 36 KHz to provide a display having the quality of an SVGA display. In another embodiment, the light bar structure 130 is not fully populated with the light conduits 142 in the horizontal x-axis direction and the beams 172 are scanned in the horizontal x-axis direction by moving the curved mirror 162 in the x-axis direction, rotating the curved mirror 162 about the z-axis, horizontally moving the light bar structure 130 in the x-axis direction, or combinations thereof.

In one embodiment, when the light conduits 142 are arranged and configured as in FIG. 5, the light bar structure 130 is moved upwardly through the entire or a substantial portion of the vertical dimension of the curved mirror 162 to scan the beams 172 of red/blue light provided by the light conduits 142b and the beams 172 of green light provided by the light conduits 142a. Then, the light bar structure 130 is moved in the x-axis direction and the light emitters 150a-150c are activated and the beams 172 are scanned by moving the light bar structure 130 downward through the entire or a substantial portion of the vertical dimension of the curved mirror 162. The light bar structure 130 may be moved a sufficient distance in the x-axis direction so that the green light provided by the light conduits 142a are reflected from the curved mirror 162, and subsequently focused by the viewer's lens 166 onto the same pixel location on the retina 168 that the beams 172 provided by the light conduits 142b were focused. Similarly, the red/blue light provided by the light conduits 142b are reflected from the curved mirror 162, and may be subsequently focused by the viewer's lens 166 onto the same pixel location on the retina 168 that the beams 172 provided by the light conduits 142a were focused. Alternatively, red, green, and blue components of pixels may be formed adjacent to one another on the retina. Accordingly, since this upward and downward scanning of the beams 172 from the light conduits 142a and 142b are performed in the same image frame, full color pixels may be generated and perceived by the viewer. This scanning pattern advantageously allows half the number of light emitters 150 and corresponding drivers to be used compared to if the light conduits 142 are arranged as in FIG. 6. Using this scanning pattern each of the output ends 151a and 151b of the light conduits 142a and 142b follows a generally elliptical path in the vertical x-z plane, although, typically the upper and lower portions of the ellipse would not be used to provide pixels.

In another embodiment, instead of moving the light bar structure 130 in the x-axis direction, the curved mirror 162 may be moved in the x-axis direction and/or rotated about the z-axis to direct the beams 172 of green light from the light conduits 142a onto the same pixel location on the viewer's retina 168 that the beams 172 provided by the light conduits 142b were focused. Similarly, the beams 172 of red/blue light provided by the light conduits 142b may be directed by the curved mirror 162 and subsequently focused by the viewer's lens 166 onto the same pixel location on the viewer's retina 168 that the beams 172 provided by the light conduits 142a were focused. Alternatively, movement of the curved mirror 162 may be used to place color components of given pixels adjacent to one another or overlapping one another on the viewer's retina 168.

In yet another embodiment, the light bar structure 130 may be maintained substantially stationary in front of the viewer's eye 163 and the scanning of the beams 172 is performed by moving the curved mirror 162 using the actuator 178. Scanning the beams 172 in the vertical z-axis direction may be performed by rotating the curved mirror 162 about the x-axis, moving the curved mirror 162 in the z-axis direction, or both. Scanning the beams 172 in the vertical x-axis direction may be performed by rotating the curved mirror 162 about the z-axis, moving the curved mirror 162 in the x-axis direction, or both.

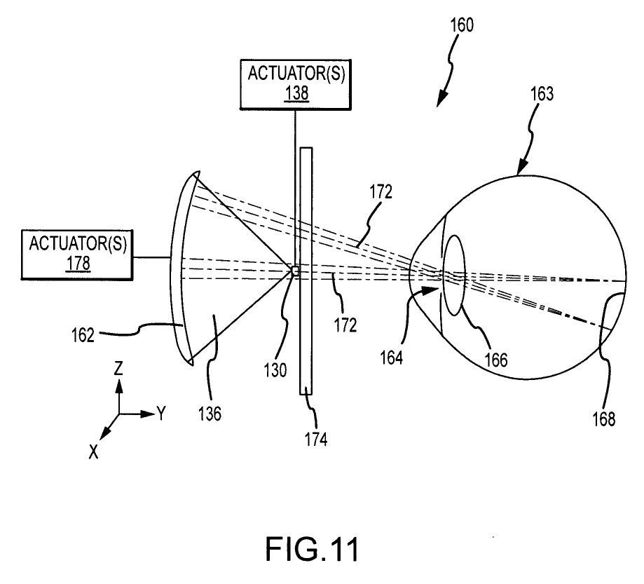

FIG. 12 shows a simplified block diagram of a display system 200 employing any of the aforementioned displays according to one embodiment. The display system 200 includes an image source 202 operable to produce an image signal 204. The image signal 204 may be a VGA signal, SVGA signal, or another suitable image signal format. The image signal 204 may include information associated with the intensity, color, and location of the pixels to be generated by the display system 200. The display system 200 further includes a controller 206 operably coupled to the display 160 having the light bar structure 130, one or more actuators 138 and/or 178, and the curved mirror 162. The controller 206 receives the image signal 204 and controls the modulation of the light emitters 150 of the light bar structure 130 and the operation of the actuator(s) 138, 178 to move the light bar structure 130 and, if applicable, the curved mirror 162 to scan the light provided by the light bar structure 130 to effect image generation.

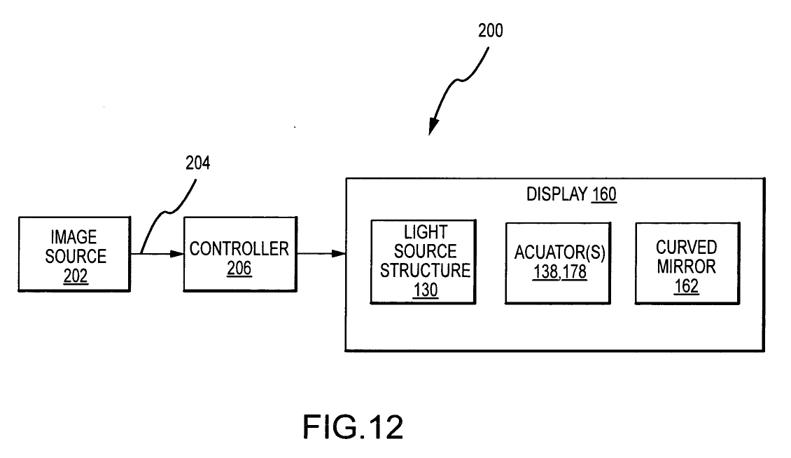

FIG. 13 shows a block diagram of a system 250, such as a camera, that uses the scanned light display 160 to provide images to the eye of a viewer 163 according to one embodiment. An optional digital image capture subsystem 262 is controlled by a microcontroller 258 to continuously or selectively capture still or video images according to user control received via user interface 256. According to the wishes of the user, images or video may be stored in local storage 260 and/or alternatively may be sent to an external system through input/output interface 254. The system 250 may be controlled to display a live image that is received by the image capture system 262 or alternatively may be controlled to display stored images or video retrieved from the storage 260.

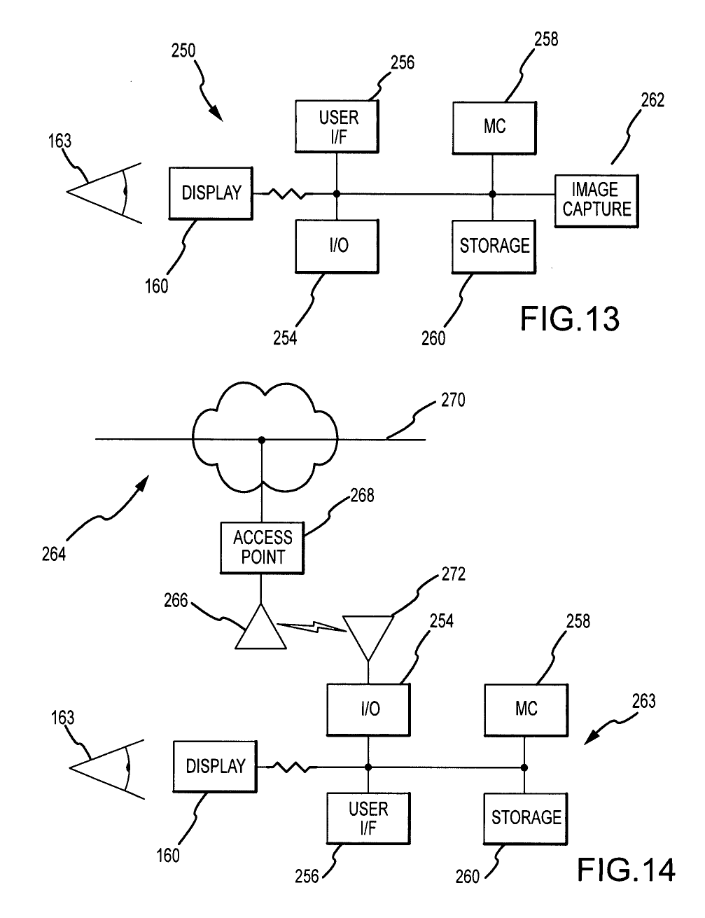

FIG. 14 shows a block diagram of a media viewing system 263 that uses the scanned light display 160 to provide images to the eye of a viewer 163 according to one embodiment. The media viewing system 263 receives images from media delivery infrastructure 264, which may for example include video or still image delivery services over the Internet, a cellular telephone network, a satellite system, terrestrial broadcast or cable television, a plug-in card, a CD or DVD, or other media sources known in the art. For example, the media delivery infrastructure 264 may include a video gaming system for providing a video gaming image, a digital camera, or a recorded media player. In the embodiment of FIG. 14, an access point 268 provides a signal via wireless or non-wireless interface 266 to an input/output of the media viewer 263 via a wireless interface 272 interfaced to the remainder of the media viewer 263 via communication interface 254. As used herein, the term communication interface may be used to collectively refer to the wireless interface 272 (e.g., an antenna as shown) and the radio and/or other interface to which it is connected. Media may be delivered across the communication interface in real time for viewing on the display 160, or may alternatively be buffered by the microcontroller 258 in local storage 260. User controls comprising a user interface 256 may be used to control the receipt and viewing of media. The media viewing system 263 may, for example, be configured as a pocket media viewer, a cellular telephone, a portable Internet access device, or other wired or wireless device.

Although the invention has been described with reference to the disclosed embodiments, persons skilled in the art will recognize that changes may be made in form and detail without departing from the spirit and scope of the invention. For example, although scanning of the various embodiments have been described with reference to “vertical” and “horizontal” directions, it will be understood that scanning along other orthogonal and non-orthogonal axes may be used instead. In addition, many modifications may be made to adapt to a particular situation and the teaching of the invention without departing from the central scope. Therefore, it is intended that the invention not be limited to the particular embodiment disclosed as the best mode contemplated for carrying out the invention, but that the invention include all embodiments falling within the scope of the appended claims.

What is claimed is:

1. A light bar structure for use in a scanned light display, comprising:
an elongated support arm having a plurality of light conduits formed therein, each of the light conduits including at least one input portion and a distal output end; and
a plurality of light emitters mounted on the support arm, each of the light emitters is operable to emit light and positioned adjacent the at least one input portion of a corresponding one of the light conduits so that the light emitted from each of the light emitters is optically coupled to the corresponding one of the light conduits and output from the output end thereof as diverging light.

2. The light bar structure of claim 1 wherein the support arm includes a curved portion having a convex surface and wherein each of the distal output ends of the light conduits terminate at the convex surface.

3. The light bar structure of claim 1, further comprising a hinge attachment portion configured for attachment to a hinge mechanism, the hinge attachment portion attached to and projecting away from the support arm.

4. The light bar structure of claim 3 wherein the hinge attachment portion is integrally formed with the support arm.

5. The light bar structure of claim 1 wherein each of the light emitters comprises a plurality of light emitters.

6. The light bar structure of claim 1 wherein at least a portion of each of the light conduits is defined by a first and second reflecting portion.

7. The light bar structure of claim 6 wherein each of the light conduits comprises a dielectric plug positioned between the first and second reflecting portions.

8. The light bar structure of claim 7 wherein the dielectric plug comprises silicon dioxide.

9. The light bar structure of claim 6 wherein the first and second reflecting portions are selected from the group consisting of copper, silver, aluminum, and alloys thereof.

10. The light bar structure of claim 1 wherein the at least one input portion of each of the light conduits comprises a reflecting surface configured to direct the light out of the output end.

11. The light bar structure of claim 10 wherein the reflecting surface is oriented at a selected angle.

12. The light bar structure of claim 10 wherein the reflecting surface has a stepped configuration.

13. The light bar structure of claim 1 wherein each of the light emitters is positioned over an aperture superjacent the at least one input portion and formed in a corresponding one of the light conduits.

14. The light bar structure of claim 1 wherein the support arm comprises a semiconductor material.

15. The light bar structure of claim 14 wherein the semiconductor material comprises silicon.

16. The light bar structure of claim 1 wherein the light conduits comprise first and second light conduits each of which has at least one input portion and a distal output end.

17. The light bar structure of claim 16 wherein the first light conduit is associated with a first light emitter positioned and operable to provide light of a first color to a first input portion of a first section of the first light conduit, the first light conduit is further associated with a second light emitter positioned and operable to provide light of a second color to a second input portion of a second section of the first light conduit, the first section intersecting the second section so that the light of the first and second colors is output from the first light conduit, and the second light conduit is associated with a third light emitter positioned and operable to provide light of a third color to the second light conduit.

18. The light bar structure of claim 1 wherein each of the light emitters is operable to emit light of only one color.

19. The light bar structure of claim 1 wherein each of the light emitters is operable to emit diverging light.

20. The light bar structure of claim 1 wherein the support arm has a substantially flat surface and each of the light emitters are mounted to the substantially flat surface.

21. The light bar structure of claim 1 wherein the support arm extends generally in a first direction and each of the light conduits extends transversely through at least part of the support arm.

22. A method of fabricating a light bar structure, comprising:
forming a plurality of trenches in a substrate, each of the trenches having at least one input portion and a distal output end;
covering each of the trenches with at least one layer of material to define a plurality of light conduits;
forming an aperture in the at least one layer of material adjacent each of the input portions;
positioning a plurality of light emitters, each of the light emitters positioned adjacent one of the apertures; and
forming a support arm comprising the plurality of light conduits from the substrate.

23. The method of claim 22 wherein the substrate comprises a semiconductor material.

24. The method of claim 23 wherein the semiconductor material comprises silicon.

25. The method of claim 22 wherein the act of forming a plurality of trenches having at least one input portion and a distal output end comprises etching the substrate to form the plurality of trenches.

26. The method of claim 22, further comprising:
after the act of forming a plurality of trenches, forming a first reflecting portion on surfaces of each of the trenches; and
forming a dielectric plug within each of the trenches and over the first reflecting portion;
and wherein the act of covering each of the trenches with at least one layer of material to define a plurality of light conduits comprises forming a second reflecting portion over the dielectric plug.

27. The method of claim 22 wherein the act of forming an aperture in the layer of material adjacent each of the input portions comprises etching the aperture in the layer material.

28. The method of claim 22 wherein the act of positioning a plurality of light emitters, each of the light emitters positioned adjacent one of the apertures comprises mounting each of the light emitters over a corresponding one of the apertures.

29. The method of claim 22 wherein the act of forming a support arm comprising the plurality of light conduits from the substrate comprises etching the support arm from the substrate.

30. The method of claim 29 wherein the act of etching the support arm from the substrate comprises deep reactive ion etching.

31. The method of claim 22 wherein the act of forming a support arm comprising the plurality of light conduits from the substrate comprises forming the support arm integrally with a hinge attachment portion.

32. A scanned light display system, comprising:
at least one light bar structure, comprising:
an elongated support arm having a plurality of light conduits formed therein, each of the light conduits including at least one input portion and a distal output end; and
a plurality of light emitters mounted on the support arm, each of the light emitters is operable to emit light and positioned adjacent the at least one input portion of a corresponding one of the light conduits so that the light emitted from each of the light emitters is optically coupled to the corresponding one of the light conduits and output from the output end thereof as diverging light;
a curved mirror positioned to receive at least a portion of the diverging light and configured to substantially collimate the received diverging light; and
an actuator coupled to at least one of the at least one light bar structure and the curved mirror, the actuator operable to move the at least one light bar structure and the curved mirror relative to each other to scan the substantially collimated light to form an image.

33. The scanned light display system of claim 32 wherein the support arm includes a curved portion having a convex surface and wherein each of the distal output ends of the light conduits terminate at the convex surface.

34. The scanned light display system of claim 32, further comprising a hinge attachment portion configured for attachment to a hinge mechanism, the hinge attachment portion attached to and projecting away from the support arm.

35. The scanned light display system of claim 34 wherein the hinge attachment portion is integrally formed with the support arm.

36. The scanned light display system of claim 32 wherein each of the light emitters comprises a plurality of light emitters.

37. The scanned light display system of claim 32 wherein at least a portion of each of the light conduits is defined by a first and second reflecting portion.

38. The scanned light display system of claim 37 wherein each of the light conduits comprises a dielectric plug positioned between the first and second reflecting portions.

39. The scanned light display system of claim 38 wherein the dielectric plug comprises silicon dioxide.

40. The scanned light display system of claim 37 wherein the first and second reflecting portions are selected from the group consisting of copper, silver, aluminum, and alloys thereof.

41. The scanned light display system of claim 32 wherein the at least one input portion of each of the light conduits comprises a reflecting surface configured to direct the light toward the output end.

42. The scanned light display system of claim 41 wherein the reflecting surface is oriented at a selected angle.

43. The scanned light display system of claim 41 wherein the reflecting surface has a stepped configuration.

44. The scanned light display system of claim 32 wherein each of the light emitters is positioned over an aperture superjacent the at least one an input portion and formed in a corresponding one of the light conduits.

45. The scanned light display system of claim 32 wherein the support arm comprises a semiconductor material.

46. The scanned light display system of claim 45 wherein the semiconductor material comprises silicon.

47. The scanned light display system of claim 32 wherein each of the light conduits comprises first and second light conduits each of which has at least one input portion and a distal output end.

48. The scanned light display system of claim 47 wherein the first light conduit is associated with a first light emitter positioned and operable to provide light of a first color to a first input portion of a first section of the first light conduit, the first light conduit is further associated with a second light emitter positioned and operable to provide light of a second color to a second input portion of a second section of the first light conduit, the first section intersecting the second section so that the light of the first and second colors is output from the first light conduit, and the second light conduit is associated with a third light emitter positioned and operable to provide light of a third color to the second light conduit.

49. The scanned light display system of claim 32 wherein each of the light emitters is operable to emit light of only one color.

50. The scanned light display system of claim 32 wherein each of the light emitters is operable to emit diverging light.

51. The scanned light display system of claim 32 wherein the support arm has a substantially flat surface and each of the light emitters are mounted to the substantially flat surface.

52. The scanned light display system of claim 32 wherein the support arm extends generally in a first direction and each of the light conduits extends transversely through at least part of the support arm.

53. The scanned light display system of claim 32 wherein the support arm has a longitudinal axis that extends generally in a first direction and the actuator is operable to move the at least one light bar structure in a second direction that is substantially perpendicular to the first direction.

54. The scanned light display system of claim 32 wherein the actuator is coupled to the at least one light bar structure and operable to move the at least one light bar structure to scan the substantially collimated light in at least one dimension to form the image.

55. The scanned light display system of claim 32 wherein the support arm extends generally in a first direction; and
further comprising a control system coupled to the light emitters and the actuator, the control system being operable to couple signals to the light emitters to sequentially scan in the first direction and to couple a signal to the actuator to move the at least one light bar structure in a second direction that is substantially perpendicular to the first direction.

56. The scanned light display system of claim 32 wherein the support arm includes a curved portion having a convex surface with a curvature that corresponds to the curvature of the curved mirror and wherein each of the output ends of the light conduits terminate at the convex surface.

57. The scanned light display system of claim 32 wherein the support arm has a longitudinal axis that extends generally in a first direction and the actuator is operable to move the at least one light bar structure in a second direction that is substantially perpendicular to the first direction in a manner that maintains the distance between the output ends of the light conduits and the curved mirror substantially constant as the actuator moves the support arm in the second direction.

58. The scanned light display system of claim 32 wherein the curved mirror has a focal surface, and wherein the output ends of the light conduits are positioned substantially at the focal surface.

59. The scanned light display system of claim 58 wherein the curved mirror is a spherical mirror and the focal surface is a focal sphere.

60. The scanned light display system of claim 32 wherein the curved mirror comprises a mirror that is at least partially transparent.

61. The scanned light display system of claim 32 wherein the curved mirror comprises a spherical mirror.

62. The scanned light display system of claim 32 wherein the curved mirror comprises a Fresnel mirror.

63. The scanned light display system of claim 32 wherein the curved mirror comprises a diffractive mirror.

64. The scanned light display system of claim 32 wherein the support arm has a longitudinal axis that extends generally in a first direction; and
wherein the actuator is operable to move the curved mirror to scan the substantially collimated light in the first direction.

65. The scanned light display system of claim 32 wherein the support arm has a longitudinal axis that extends generally in a first direction and wherein the actuator is operable to move the support arm in the first direction.

66. The scanned light display system of claim 32 wherein the actuator is coupled to the curved mirror and operable to move the curved mirror to scan the substantially collimated light in at least one dimension to form the image.

67. The scanned light display system of claim 32, further comprising a control system coupled to the light emitters and the actuator, the control system being operable to couple signals to the light emitters and the actuator.

68. The scanned light display system of claim 67, further comprising an image capture system.

69. The scanned light display system of claim 67, further comprising an image generation system and wherein the control system is operable to scan the substantially collimated light to form the image responsive to a signal from the image generation system.

70. The scanned light display system of claim 69 wherein the image generation system comprises one of a video gaming system, a digital camera, a recorded media player, and a television receiver.

71. A method of generating an image by scanning light on a retina of a viewer's eye, the method comprising:
emitting light from each of a plurality of light conduits generally extending in a first direction, the light generated at each of the light conduits being reflected to the retina of the viewer's eye from a reflecting surface;
moving the light generation locations in a second direction that is generally perpendicular to the first direction; and
controlling the intensity of the light from each of the light conduits.
